(19) United States
(12) Patent Application Publication
(10) Pub. No.: US 2016/0203097 A1
(43) Pub. Date: Jul. 14, 2016

(54) Solid-State Optical Drive and Solid-State Storage Server

(71) Applicant: Guobiao ZHANG, Corvallis, OR (US)

(72) Inventor: Guobiao ZHANG, Corvallis, OR (US)

(73) Assignee: HangZhou HaiCun Information Technology Co., Ltd., HangZhou (CN)

(21) Appl. No.: 14/994,137

(22) Filed: Jan. 12, 2016

(30) Foreign Application Priority Data
Jan. 12, 2015 (CN) 201510014929.4

(51) Int. Cl. G06F 13/40; G11C 5/02; G06F 13/36

(52) U.S. Cl. CPC G06F 13/4068; G06F 13/36; G11C 5/02

(57) ABSTRACT

The present invention discloses a content delivery network (CDN) based on solid-state optical drive (SSO). Like a solid-state (hard) drive (SSD) is a solid-state version of a hard-disk drive (HDD), the SSO is a solid-state version of CD-tower. Because an SSO stores a content library (CL) at a reasonable cost, the CL can be deployed at the edges of the CDN instead of only at the origin.

### CROSS-REFERENCE TO RELATED APPLICATIONS

This claims benefits of a Chinese (CN) patent application, “Solid-State Storage Server”, Application Serial No. 201510014929.4, filed Jan. 12, 2015.

### BACKGROUND

1. Technical Field of the Invention

The present invention relates to the field of communication network, more particularly to content delivery network (CDN).

2. Prior Arts

A content delivery network (CDN) is a network of geographically-distributed content delivery nodes that are arranged for efficient delivery of digital contents. As disclosed in FIG. 1, a typical CDN comprises three tiers: an origin 710 (including an origin server 712 and a hard-disk drive array 714), intermediates 720 (including intermediate servers 722) and edges 730 (including edge servers 732). The backbones 716 link the origin 710 and the intermediates 720, while the backbones 726 link the intermediates 720 and the edges 730. The edges 730 directly serves end users. The content library (CL) is generally stored at the origin 710, while the intermediate servers 722 and the edge servers 732 are cache servers, which store temporary copies of popular contents. The edge servers 732 caches the most popular contents, while the intermediate servers 722 caches the most popular of what is left. The CDNs have been deployed nationwide for high-definition (HD) videos (i.e. HD-CDN) and for home/office users. However, the existing CDNs are not adequate for ultra-high-definition (UHD) videos and for mobile users.

UHD-CDN distributes UHD videos (e.g. 4k videos, naked-eye 3D videos, holographic videos). Because its data rate is much higher (at least 10×) than the HD videos, the UHD-CDN requires a system-wide overhaul of the existing CDN (i.e. HD-CDN). This includes increasing the capacity of servers and the bandwidth of backbones at all tiers (i.e. origin, intermediates, and edges). Because it requires re-building a new set of CDN infra-structure, the UHD-CDN would be extremely expensive.

Mobile CDN provides mobile users with contents (e.g. videos) when they are commuting (e.g. car-pooling, using public transit such as bus or metro) or traveling (e.g. taking bus, train, or airplane). The existing wireless (e.g. 3G, or 4G) networks are not adequate for the mobile CDN: first of all, the mobile data is too expensive for video transmission; secondly, because its bandwidth is shared, the existing mobile network only allows a small number of mobile users to view videos at the same time.

To implement a mobile CDN, one approach is to add the next-generation wireless (e.g. 5G) network to the existing CDN. To be more specific, each base station comprises a base-station server (which acts as an edge server) and caches popular contents. However, when transmitting videos to a large number of riders on a high-speed train (or other high-speed vehicles), complex caching schemes need to be developed because a high-speed train stays in a cell only for a short time (could be as short as a few seconds).

Another approach to implement the mobile CDN is using an on-board wireless server. It stores the content library (CL) on board and transmits contents therein through a wireless router. Because of the tough environment it runs at, the on-board wireless server preferably uses solid-state drive (SSD) for content storage instead of hard-disk drive (HDD). The high price of SSD prohibits the on-board wireless server from storing a large CL and therefore, riders have a limited selection.

On another front, solid-state storage has made significant progress in recent years. Since the contents distributed in a CDN are mostly published contents (e.g. movies, songs, books and other multimedia contents) which are permanent and do not require “re-write”, one type of solid-state storage of particular interest to the CDN is printed memory, whose data is permanently recorded using a printing method during manufacturing. Compared with the “re-writable” memory, the printed memory generally has a much larger capacity and a much lower cost.

U.S. Pat. No. 5,835,396 issued to Zhang on Nov. 3, 1998 discloses a three-dimensional printed memory (3D-P), a.k.a. three-dimensional mask-programmable read-only memory (3D-MPROM). As disclosed in FIG. 2, it comprises four printed-memory levels 20a-20d. Among them, the memory level 20a make contact with the substrate 11 through the contact vias 20av (the contact vias for the memory levels 20b-20d are not shown). The memory levels (e.g. 20c and 20d) are separated by an insulating dielectric 13. Each memory level comprises a plurality of word lines (e.g. 12), bit lines (e.g. 14) and memory cells (e.g. 18). The data stored in each memory cell 18 is determined by the existence or absence of a printed layer 16: the memory cell 18 stores digital “0” if the printed layer 16 exists; and digital “1” if it is absent. The data are printed into the memory level (e.g. 20a) during manufacturing. Without the “re-write” requirement, 3D-P has a simple design and a good manufacturability. A 3D-P could comprise eight vertically stacked memory levels or more. At the 25 nm node, a 3D-P die comprising eight memory levels can store 320 Gb (for SLC) or 640 Gb (for MLC). Here, SLC refers to a memory cell which stores a single bit; and MLC refers to a memory cell which stores two bits. For reason of simplicity, the diode in each 3D-P cell is not drawn.

To further improve the capacity, multiple 3D-P dice are vertically stacked in a 3-D module. A 3D-P-based 3-D module is referred to as a micro optical drive (uO). Similar to an optical drive, an uO permanently stores published contents. However, an uO does not use optical means to retrieve data and comprises no mechanical parts. It has a much smaller physical size but stores much more data than any optical drive.

U.S. Pat. No. 7,952,903 issued to Zhang on May 31, 2011 discloses a three-dimensional-memory-based three-dimensional module (3D²-M²). Among different types of 3D²-M², the 3D-P-based 3D²-M² is, in fact, an uO. FIG. 3A is an external view of an uO 100. In this figure, the uO takes the form of a TF card. It may take other forms (e.g. an eMMC card). Like a flash-based TF card, this uO has a dimension of 15 mm×11 mm×1 mm. FIG. 2B is its internal view. It comprises two 3D-P dice 10a, 10b vertically stacked above the substrate 130. The 3D-P die 10b offsets against the 3D-P die 10a in such a way that the contacts 120a on the die 10a are exposed. Bond wires couple the dice 10a, 10b and the substrate 130. The stacked dice 10a, 10b are housed in a protective package 120. An uO could comprise eight vertically stacked 3D-P dice or more. At the 25 nm node, an uO can store 320 GB (for SLC) or 640 GB (for MLC).

Although it has a much larger capacity and a much lower cost than the re-writable memory, from a system's perspective, the printed memory (including 3D-P and uO) is not convenient to handle new publications. In a typical electronic system, the memory modules are permanently soldered onto the mother board. It would be difficult to add new modules to accommodate new publications. For an electronic system comprising expansion slots, because it is customary to have only a small number (1 to 2) of expansion slots, this electronic system cannot accommodate a large number of new issuances (e.g. a new issuance each month).

### OBJECTS AND ADVANTAGES

It is a principle object of the present invention to provide a content delivery network (CDN) for ultra-high-definition (UHD) videos at a reasonable cost.

It is a further object of the present invention to provide a CDN for mobile users at a reasonable cost.

It is a further object of the present invention to provide a printed-memory device which can accommodate a large number of new issuances.

In accordance with these and other objects of the present invention, the present invention discloses an UHD-CDN and a mobile CDN, as well as their associated solid-state optical drive (SSO) and solid-state storage server (SSS-server).

### SUMMARY OF THE INVENTION

The present invention discloses a solid-state optical drive (SSO) and a solid-state storage server (SSS-server). The SSS-server comprises at least a solid-state (hard) drive (SSD) and at least a solid-state optical drive (SSO). Like an SSD is a solid-state version of a hard-disk drive (HDD), the SSO is a solid-state version of a CD-tower. In other words, the SSD stores re-writable data (mostly user data), while the SSO stores permanent data (mostly published contents). The SSO comprises a large number (>10, e.g. 127) of expansion slots. A micro optical drive (uO) can be inserted in or pulled out from the expansion slot. When a new publication is released, a new uO can be inserted into an empty expansion slot. Alternatively, the new uO can replace another uO which has already occupied a expansion slot. When fully loaded, an SSO can store a huge content library (CL). For example, an uO can store 640 GB and an SSO with 127 expansion slots can store 80 TB, enough for all movies produced over ten years.

The present invention further discloses an SSO-based UHD-CDN. Because an SSO can store a content library (CL) at a reasonable cost, the CL can be deployed at more nodes than the existing CDN. To be more specific, the CL can be deployed at the edges. This is different from the existing CDN where the CL is deployed only at the origin with the edges caching a portion of the CL. Thus, the desired UHD-videos can be directly fetched from the edges without going through the backbones to the intermediates and to the origin. As a result, an UHD-CDN can be realized without upgrading the backbones, the intermediates and the origin.

The present invention further discloses an SSO-based mobile CDN. Similar to the UHD-CDN, the base-station server, which acts as an edge server for the mobile CDN, comprises an SSO which stores the CL. Because the desired videos can be directly fetched from the base-station servers, the mobile CDN does not need to use complex caching schemes. In addition, the SSO can also be used in an on-board wireless server. Because the SSO has a lower cost than the SSD, the on-board wireless server can store more contents.

### BRIEF DESCRIPTION OF THE DRAWINGS

FIG. 1 is the topology of an existing content delivery network (CDN) (prior art);

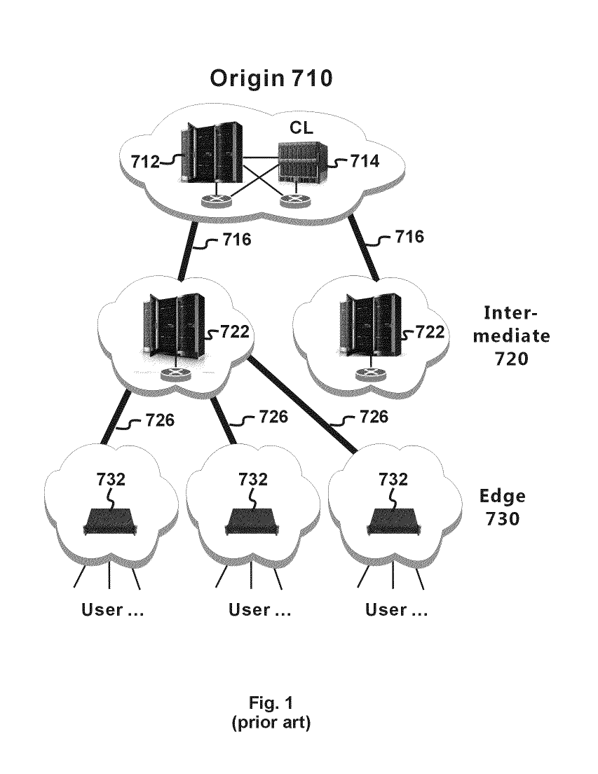

FIG. 2 is a cross-sectional view of a three-dimensional printed memory (3D-P);

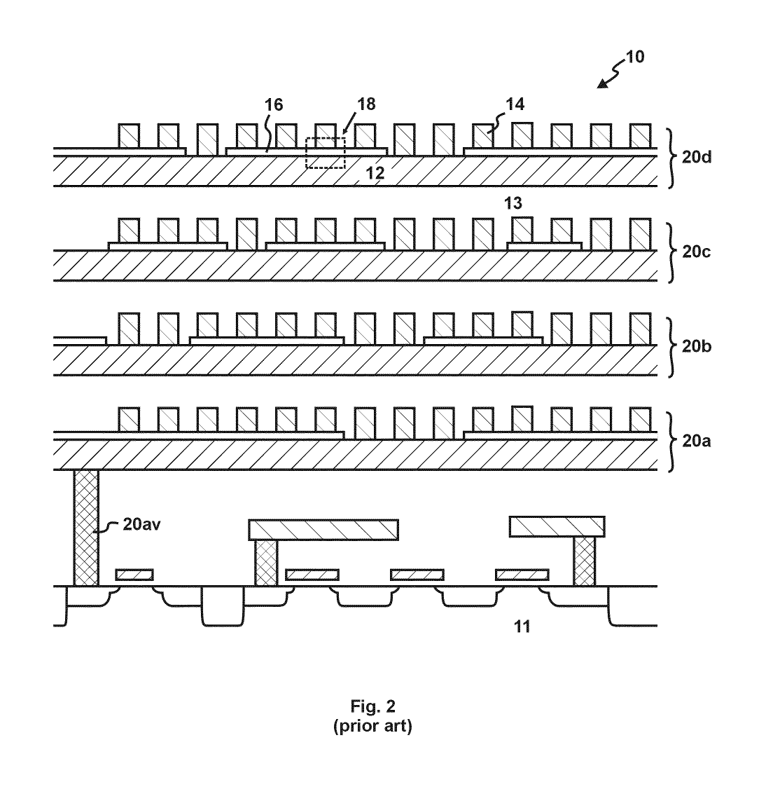

FIG. 3A is an external view of a micro optical drive (uO); FIG. 3B is an internal view of an uO;

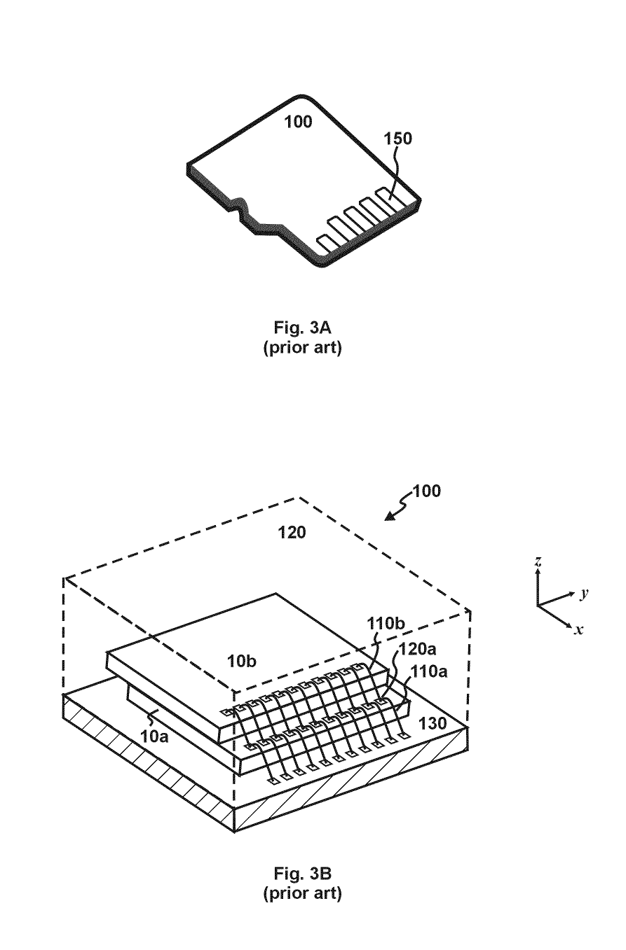

FIG. 4A is a cut-away view of a solid-state optical drive (SSO); FIG. 4B is a circuit block diagram of an SSO.

FIG. 5A illustrates the evolution of a storage server; FIG. 5B is a block diagram of a solid-state storage server (SSS-server);

FIG. 6 illustrates a preferred SSO-based UHD-CDN;

FIG. 7 illustrates a preferred SSO-based mobile CDN;

FIG. 8 illustrates another preferred SSO-based mobile CDN.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

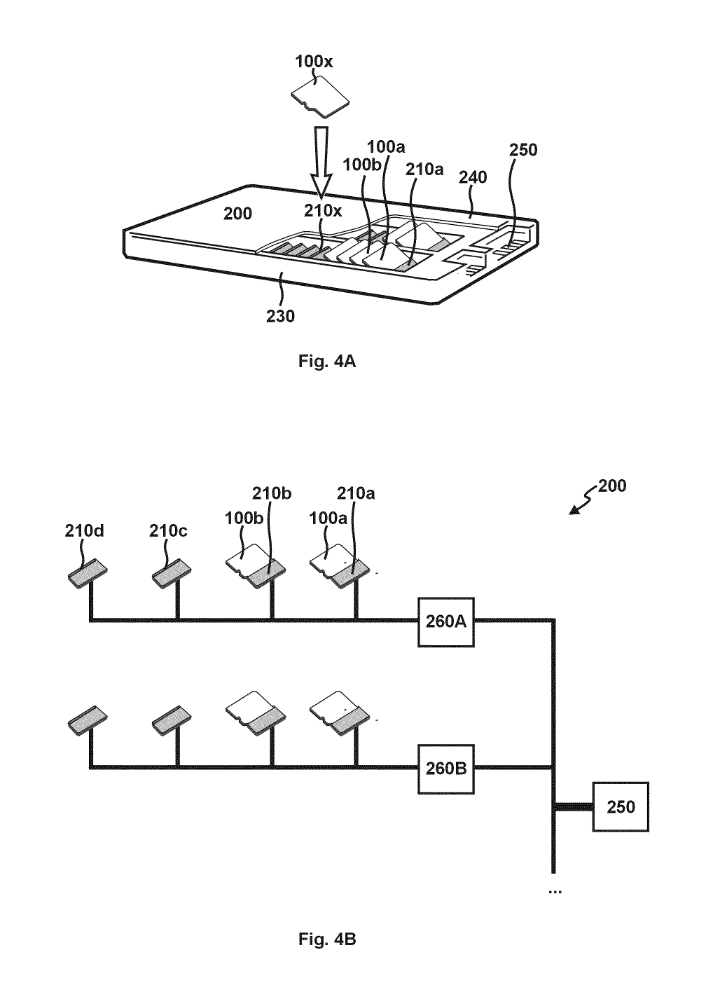

Referring now to FIGS. 4A-4B, a solid-state optical drive (SSO) is disclosed. It comprises a base 230 and an interface 250. The base 230 further comprises a large number (>10) of expansion slots 210a . . . 201x . . . The expansion slots (e.g. 210a) have the micro optical disks (uO) 100a, 100b inserted, while the expansion slots (e.g. 210x) are empty. The uOs 100a, 100b are coupled to the interface 250 through the expansion slots (referring to FIG. 4B). The top cover 240 is optional. It can be turned over in such a way that a new uO 100x can be inserted into an empty expansion slot 210x.

The preferred SSO 200 of FIG. 4B uses an USB protocol, i.e. the interface 250 is coupled to the hubs 260A, 260B using the USB protocol. The hub 260A is coupled to the expansion slots (e.g. 210a, 210d . . . ) and the uOs (e.g. 210a, 210b . . . ) inserted therein. Because an USB hub can be coupled to up to 127 devices, the SSO 200 could comprise 127 expansion slots or more. The SSO 200 has a volume of ˜63 cm³ (assuming a distance of 1.5 mm between uOs), which is about the same volume as a portable HDD (with a volume of 54 m³). Considering that an uO has a storage capacity of 640 GB (MLC) and each UHD movie needs 20 GB, an uO can store 32 movies, which is about the number of movies released each month. Accordingly, a CDN operator may insert a new uO 210x (containing all movies released in this month) into the SSO 200 each month. A fully loaded SSO 200 could have a storage capacity of ˜80 TB and can store all movies produced over ten years.

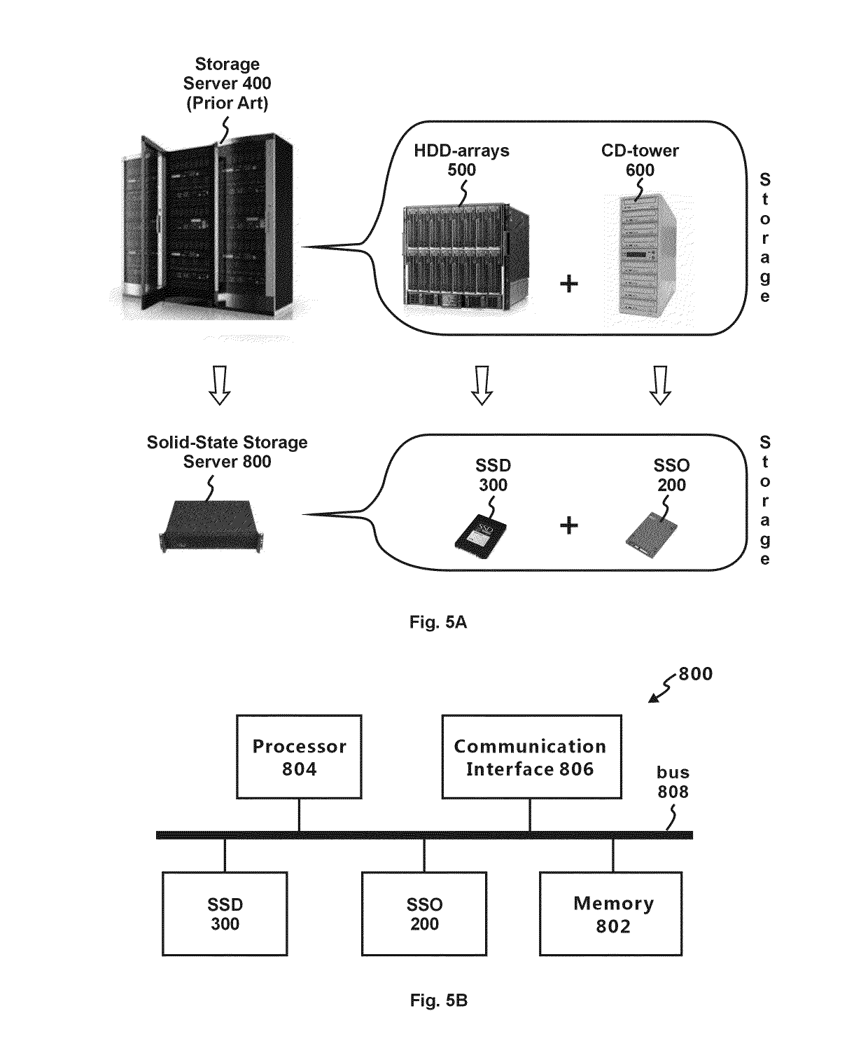

FIG. 5A illustrates the evolution of a storage server. In prior arts, the storage media for a storage server 400 comprises an HDD-array 500 (which stores re-writable data) and a CD-tower 600 (which stores published contents). Because it uses mechanical hard disks, the HDD-array 500 has a poor random read/write capability. Similarly, because it uses mechanical optical disks, the CD-tower also has poor random read capability. The solid-state storage server (SSS-server) 800 replaces the HDD-array 500 and CD-tower 600 with an SSD 300 and SSO 200. Because the SSD 300 and the SSO 200 are both solid-state storages and contain no mechanical parts, they have excellent random read/write capability. Note that, the SSO 200 has a better data retention and a lower cost than the SSD 300.

FIG. 5B is a block diagram of an SSS-server 800. It comprises a processor 804, a memory 802, at least an SSD 300, at least an SSO 200 and at least a communication interface 806. All of these devices are coupled through a bus 808. The SSD 300 stores re-writable data, while the SSO 200 stores published contents. The processor 804, the memory 802, the communication interface 806 and the bus 808 are similar to a conventional storage server.

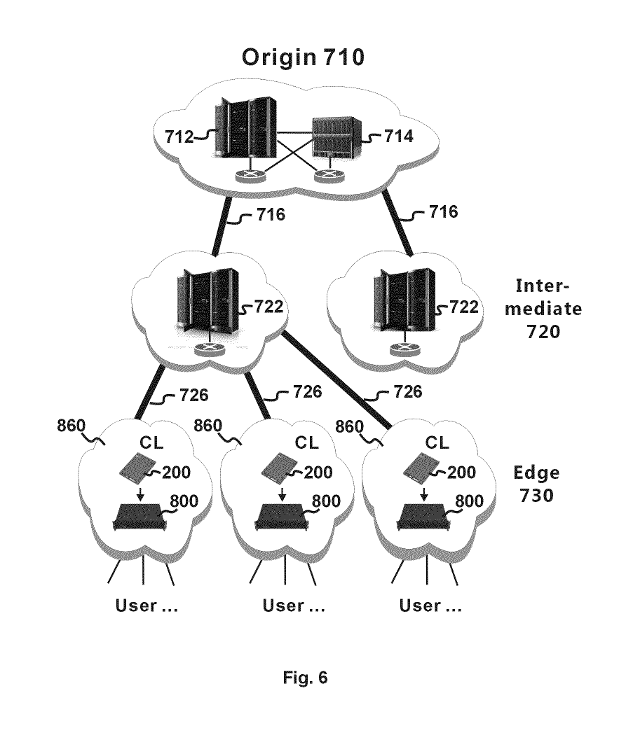

FIG. 6 illustrates a preferred SSO-based UHD-CDN. In this preferred tiered distribution, the content libraries (CL) are deployed at the edges 730. The media server 860 at the edge 730 (i.e. edge server) is an SSS-server 800. It comprises at least an SSO 200, which stores the CL. The media server 860 directly transmits the contents in the CL to the end users. Because the media server 860 does not have to fetch contents from the intermediates 720 and the origin 710, the pressures on the backbones 716, 726 will be significantly lessened. Accordingly, the SSO-based UHD-CDN does not require upgrading the backbones 716, 726, the intermediates 720 and the origin 710 to distribute the UHD-videos.

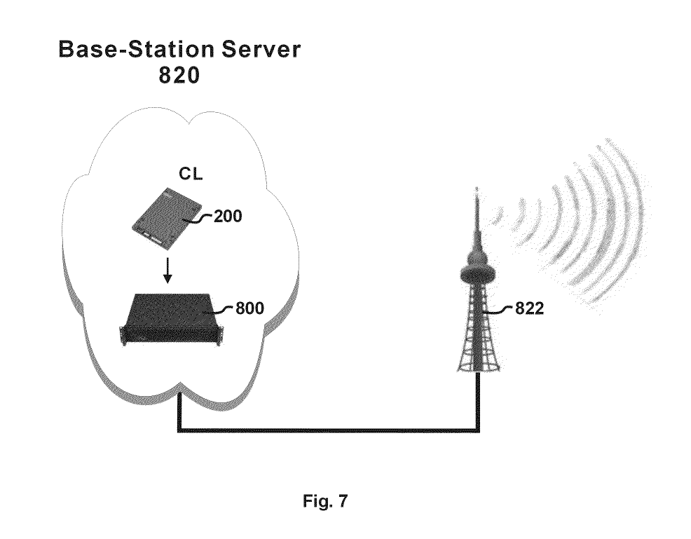

FIG. 7 illustrates a preferred SSO-based mobile CDN. It is suitable for the next-generation (e.g. 4G, 5G) network. A base-station server 820 acts as its edge server, which comprises an SSS-server 800. The SSS-server 800 comprises at least an SSO 200 for storing the CL. The base-station server 820 transmits the contents in the CL to a base-station antenna 822, and then to end users through the cellular signals. Because the CL is located at the base-station server 820, it is very easy to transmit contents to end users and realize mobile CDN.

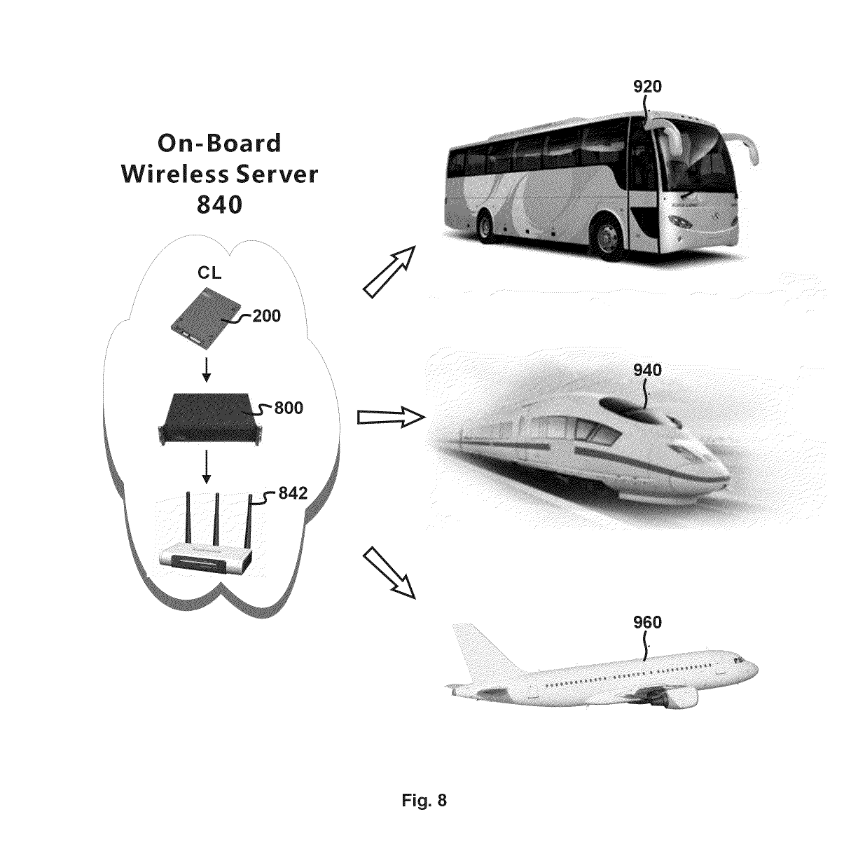

FIG. 8 illustrates another preferred SSO-based mobile CDN. It uses an on-board wireless (e.g. WiFi) server 840, which can provide contents to riders in a bus 920, a train 940 and an airplane 960. The on-board wireless server 840 comprises an SSS-server 800. The SSS-server 800 comprises an SSO 200 for storing the CL. The on-board wireless server 840 transmits the contents in the CL to a WiFi router 842, and then to end users through the WiFi signals. Because the SSO 200 is less expensive than the SSD 300, this on-board wireless server 840 can provide riders with more contents at a reasonable cost.

While illustrative embodiments have been shown and described, it would be apparent to those skilled in the art that may more modifications than that have been mentioned above are possible without departing from the inventive concepts set forth therein. The invention, therefore, is not to be limited except in the spirit of the appended claims.

What is claimed is:

1. A solid-state optical drive (SSO), comprising:
an interface;
at least a micro optical disk (uO) for storing permanent information;
at least ten expansion slots coupled to said interface, wherein said uO can be inserted in or pulled out from a selected one of said expansion slots;
wherein said uO comprises a plurality of vertically stacked three-dimensional printed memory (3D-P) dice, each of said 3D-P dice comprising a plurality of vertically stacked printed-memory levels.

2. The SSO according to claim 1, wherein said 3D-P dice are vertically stacked above the substrates of said 3D-P dice.

3. The SSO according to claim 1, wherein said printed-memory levels are vertically stacked above the substrate of the 3D-P die.

4. A solid-state storage server (SSS-server), comprising:
a processor;
a communication interface coupled to said processor;
at least a solid-state hard drive (SSD) for storing re-writable data;
at least a solid-state optical drive (SSO) for storing a content library (CL), said SSO transmitting contents in said CL through said communication interface under the control of said processor;
wherein said SSO comprises an interface and at least ten expansion slots coupled to said interface, wherein a micro optical drive (uO) can be inserted in or pulled out from a selected one of said expansion slots.

5. The SSS-server according to claim 4, wherein said SSS-server is a media server for directly transmitting contents from said CL to end users.

6. The SSS-server according to claim 5, wherein said media server is an edge server in an ultra-high-definition (UHD) content delivery network (CDN).

7. The SSS-server according to claim 4, wherein said SSS-server is a base-station server for directly transmitting contents from said CL to end users through a base-station antenna.

8. The SSS-server according to claim 7, wherein said base-station server is an edge server in a mobile content delivery network (CDN).

9. The SSS-server according to claim 4, wherein said SSS-server is a on-board wireless server for directly transmitting contents from said CL to end users through a wireless router.

10. The SSS-server according to claim 9, wherein said on-board wireless server is an edge server in a mobile content delivery network (CDN).

11. An edge server in a content delivery network (CDN), comprising:
a processor;
a communication interface coupled to said processor;
at least a solid-state optical drive (SSO) for storing a content library (CL), said SSO transmitting contents in said CL through said communication interface under the control of said processor;
wherein said SSO comprises an interface and a plurality of expansion slots coupled to said interface, wherein a micro optical drive (uO) can be inserted in or pulled out from a selected one of said expansion slots.

12. The edge server according to claim 11, further comprising a solid-state hard drive (SSD) for storing re-writable data.

13. The edge server according to claim 11, wherein said edge server is a media server for directly transmitting contents from said CL to end users.

14. The edge server according to claim 11, wherein said CDN is an ultra-high-definition (UHD) CDN.

15. The edge server according to claim 11, wherein said edge server is a base-station server for directly transmitting contents from said CL to end users through a base-station antenna.

16. The edge server according to claim 11, wherein said edge server is a on-board wireless server for directly transmitting contents from said CL to end users through a wireless router.

17. The edge server according to claim 11, wherein CDN is a mobile CDN.

18. The edge server according to claim 11, wherein said uO comprises a plurality of vertically stacked three-dimensional printed memory (3D-P) dice, each of said 3D-P dice comprising a plurality of vertically stacked printed-memory levels.

19. The edge server according to claim 18, wherein said 3D-P dice are vertically stacked above the substrates of said 3D-P dice.

20. The edge server according to claim 18, wherein said printed-memory levels are vertically stacked above the substrate of the 3D-P die.
